(19) United States
(12) Patent Application Publication
(10) Pub. No.: US 2014/0077984 A1
(43) Pub. Date: Mar. 20, 2014

(54) DELTA-SIGMA MODULATOR USING HYBRID EXCESS LOOP DELAY ADJUSTMENT SCHEME AND RELATED DELTA-SIGMA MODULATION METHOD

(71) Applicant: MEDIATEK INC., Hsin-Chu (TW)

(72) Inventor: Yun-Shiang Shu, Hsinchu County (TW)

(73) Assignee: MEDIATEK INC., Hsin-Chu (TW)

(21) Appl. No.: 14/022,182

(22) Filed: Sep. 9, 2013

Related U.S. Application Data
(60) Provisional application No. 61/701,164, filed on Sep. 14, 2012.

(51) Int. Cl. H03M 3/00

(52) U.S. Cl. CPC H03M 3/30
USPC 341/143

(57) ABSTRACT

A delta-sigma modulator has a delta-sigma modulation loop and a plurality of excess loop delay (ELD) adjustment circuits. The delta-sigma modulation loop converts an analog input into a digital output. The ELD adjustment circuits perform different ELD adjustments according to the digital output for jointly adjusting an ELD of the delta-sigma modulation loop. Besides, a delta-sigma modulation method includes at least the following steps: converting an analog input into a digital output through a delta-sigma modulation loop; and employing different ELD adjustment schemes for jointly adjusting an ELD of the delta-sigma modulation loop according to the digital output.

### CROSS REFERENCE TO RELATED APPLICATIONS

This application claims the benefit of U.S. provisional application No. 61/701,164, filed on Sep. 14, 2012 and incorporated herein by reference.

### BACKGROUND

The disclosed embodiments of the present invention relate to converting an analog signal into a digital signal, and more particularly, to a delta-sigma modulator using a hybrid excess loop delay adjustment scheme (i.e., more than one excess loop delay adjustment circuit) and related delta-sigma modulation method.

Analog techniques have dominated signal processing for years, but digital techniques are encroaching into this domain. An analog-to-digital converter is needed to convert an analog signal into a digital signal, thus allowing the signal to be processed in a digital domain. For example, a delta-sigma analog-to-digital converter (ΔΣ ADC) may be used for converting analog signals over a wide range of frequencies, from DC (direct current) to several megahertz. In general, a core part of the delta-sigma analog-to-digital converter is a delta-sigma modulator which is responsible for digitizing the analog input signal and reducing noise at lower frequencies. In this stage, the architecture implements a function called noise shaping that pushes low-frequency noise (e.g., quantization noise) up to higher frequencies outside the in-band (i.e., the band of interest). Noise shaping is one of the reasons that the delta-sigma analog-to-digital converters are well-suited for low-frequency, higher-accuracy applications.

Most often, the delta-sigma analog-to-digital converters are implemented with the use of discrete topologies. However, the input bandwidth is limited by the speed at which the filter's sampler can operate. The use of the continuous-time delta-sigma analog-to-digital converters provides some improvements. The advantage lies in the fact that no sampling is performed within the filter, so the restriction of the maximum sampling frequency is only imposed on the sampler within the quantizer. Ideally, a digital-to-analog converter (DAC) disposed at the feedback path should respond immediately to the quantizer clock edge. However, there would be a finite delay from the quantizer sampling to the feedback DAC transition. This delay varies with the difference between the quantizer input and the quantization levels. As the timing errors are continuously accumulated at integrator(s) within a loop filter through the feedback DAC, the overall performance of the continuous-time delta-sigma modulator degrades. To avoid this effect, the quantizer output are usually latched by a delayed clock to fix the quantizer delay, thus resulting in an constant excess loop delay (ELD), which shifts the overall signal and noise transfer function of the continuous-time delta-sigma modulator from the desired one. Thus, there is a need for an excess loop delay adjustment/compensation scheme.

### SUMMARY

In accordance with exemplary embodiments of the present invention, a delta-sigma modulator using a hybrid excess loop delay adjustment scheme (i.e., more than one excess loop delay adjustment circuit) and related delta-sigma modulation method are proposed to solve the above problem.

According to a first aspect of the present invention, an exemplary delta-sigma modulator is disclosed. The exemplary delta-sigma modulator includes a delta-sigma modulation loop and a plurality of excess loop delay (ELD) adjustment circuits. The delta-sigma modulation loop is arranged to convert an analog input into a digital output. The ELD adjustment circuits are arranged to perform different ELD adjustments according to the digital output for jointly adjusting an ELD of the delta-sigma modulation loop.

According to a second aspect of the present invention, an exemplary delta-sigma modulation method is disclosed. The exemplary delta-sigma modulation method includes at least the following steps: converting an analog input into a digital output through a delta-sigma modulation loop; and employing different ELD adjustment schemes for jointly adjusting an ELD of the delta-sigma modulation loop according to the digital output.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a delta-sigma modulator using a first excess loop delay adjustment scheme.

FIG. 2 is a diagram illustrating a delta-sigma modulator using a second excess loop delay adjustment scheme.

FIG. 3 is a diagram illustrating a delta-sigma modulator using a third excess loop delay adjustment scheme.

FIG. 4 is a diagram illustrating a delta-sigma modulator using a fourth excess loop delay adjustment scheme.

FIG. 5 is a diagram illustrating a delta-sigma modulator using a fifth excess loop delay adjustment scheme.

FIG. 6 is a schematic diagram illustrating a delta-sigma modulator using a hybrid excess loop delay adjustment scheme according to an embodiment of the present invention.

FIG. 7 is a diagram illustrating one exemplary delta-sigma modulator design based on the structure shown in FIG. 6.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

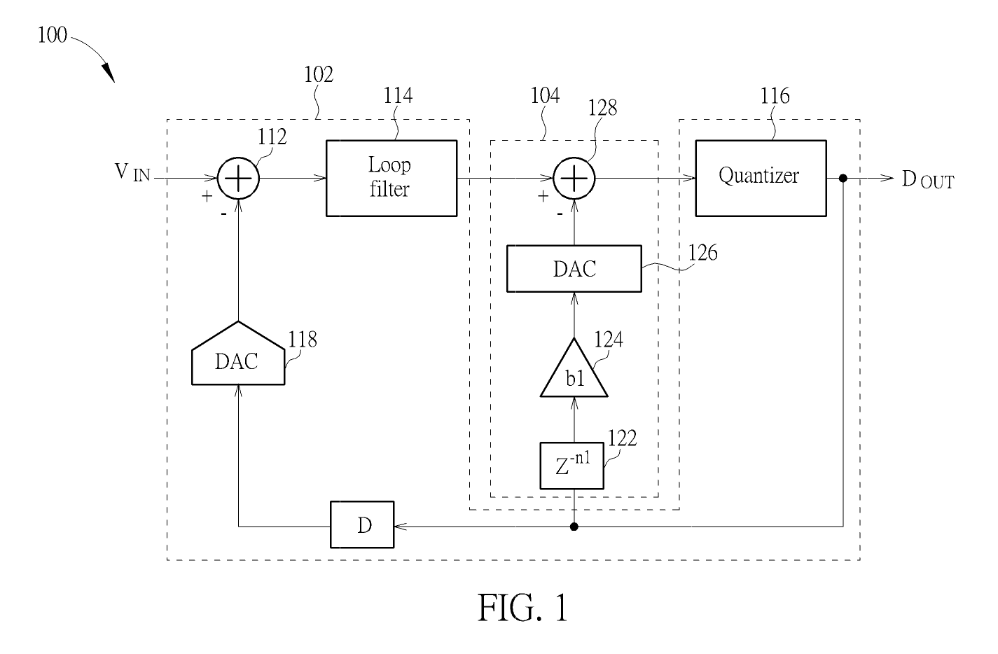

FIG. 1 is a diagram illustrating a delta-sigma modulator using a first excess loop delay (ELD) adjustment scheme. The delta-sigma modulator 100 includes a delta-sigma modulation loop 102 and an ELD adjustment circuit 104. The delta-sigma modulation loop 102 includes an adder 112 (which may be implemented using a difference amplifier to perform analog signal subtraction), a loop filter 114 (which may include one or more integrators/resonators), a quantizer 116 acting as an analog-to-digital converter (ADC), and a digital-to-analog converter (DAC) 118 located on a feedback path between an output node of the quantizer 116 and one input node of the adder 112. The delta-sigma modulation loop 102 is arranged for receiving an analog input V_{IN}, and converting the analog input V_{IN} into a digital output D_{OUT}. As a person skilled in the art should readily understand the operational principle of the delta-sigma modulator 102, further description is omitted here for brevity.

Besides, the delay block denoted by “D” represents the delay time from the quantizer sampling to the feedback DAC transition. This ELD affects the behavior of the delta-sigma modulation loop 102, and may cause performance degradation of the delta-sigma modulation loop 102 or make the delta-sigma modulation loop 102 becomes unstable. In this example, the ELD is adjusted/compensated by an additional feedback to an input node of the quantizer 116. As shown in FIG. 1, the ELD adjustment circuit 104 has at least a delay stage 122, a gain stage 124, a DAC 126, and an adder 128 (which may be implemented using a difference amplifier to perform analog signal subtraction). The delay stage 122 is arranged to delay the digital output D_{OUT} by n1*Ts, where Ts is the sampling period of the quantizer 116, and n1 may be any value required by ELD adjustment/compensation. The gain stage 124 multiplies a delayed version of the digital output D_{OUT} by a feedback coefficient b1. As the additional feedback for ELD adjustment/compensation is coupled to the analog input of the quantizer 116, the ELD adjustment circuit 104 with analog ELD adjustment is employed. Hence, the DAC 126 converts the digital sample generated from the gain stage 124 into an analog signal, and the adder 128 performs analog summation based on analog signals generated from the loop filter 114 and the DAC 126.

With regard to the ELD adjustment scheme shown in FIG. 1, the ELD adjustment is applied to the analog input of the quantizer 116, where the quantizer 116 has fixed quantization levels. Alternatively, the adder 128 for the ELD adjustment may be realized by changing quantization levels of the quantizer 116 with the analog input of the quantizer kept intact. More specifically, decreasing quantization levels of the quantizer 116 is equivalent to increasing the analog input of the quantizer 116, and increasing quantization levels of the quantizer 116 is equivalent to decreasing the analog input of the quantizer 116. The same objective of mitigating effects caused by the ELD is achieved through changing quantization levels of the quantizer 116.

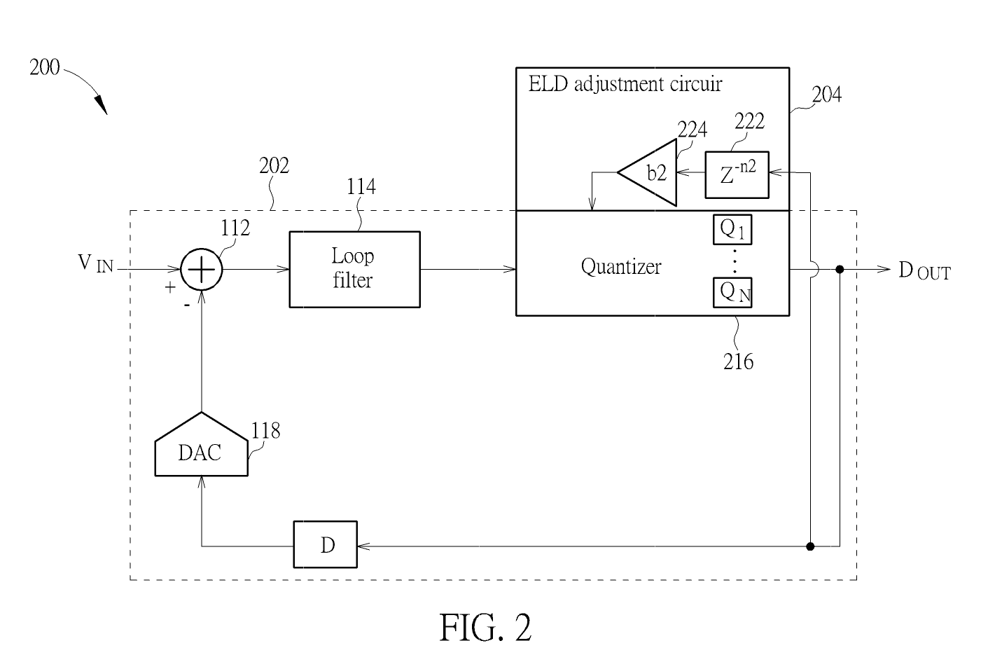

Please refer to FIG. 2, which is a diagram illustrating a delta-sigma modulator using a second ELD adjustment scheme. The delta-sigma modulator 200 includes a delta-sigma modulation loop 202 and an ELD adjustment circuit 204. The delta-sigma modulation loop 202 includes a quantizer 216 with switchable quantization levels Q₁-Q_{N} controlled by digital logics, and further includes the aforementioned adder 112, loop filter 114 and DAC 118. The ELD adjustment circuit 204 has at least a delay stage 222 and a gain stage 224. The delay stage 222 is arranged to delay the digital output D_{OUT} by n2*Ts, where Ts is the sampling period of the quantizer 216, and n2 may be any value required by ELD adjustment/compensation. The gain stage 224 multiplies a delayed version of the digital output D_{OUT} by a feedback coefficient b2.

In one exemplary design, the digital sample generated from the gain stage 224 may be referenced for selecting part of the quantization levels Q₁-Q_{N}, where the selected quantization levels are used to digitize the analog signal generated from the loop filter 114 into the digital output D_{OUT}. In another exemplary design, all of the quantization levels Q₁-Q_{N} are used to digitize the analog signal into binary bits, and the digital sample generated from the gain stage 224 may be referenced for selecting part of the binary bits as the digital output D_{OUT}. To put it simply, the ELD adjustment circuit 204 with digital ELD adjustment is implemented in the delta-sigma modulator 200 to control switching/selection of quantization levels in a digital manner.

With regard to the ELD adjustment scheme shown in FIG. 1, the ELD adjustment is applied to the analog output of the loop filter 114, where a dedicated summing circuit (i.e., adder 128) is needed. Alternatively, the dedicated summing circuit (i.e., the adder 128) may be avoided by reusing the existing components in the loop filter 114.

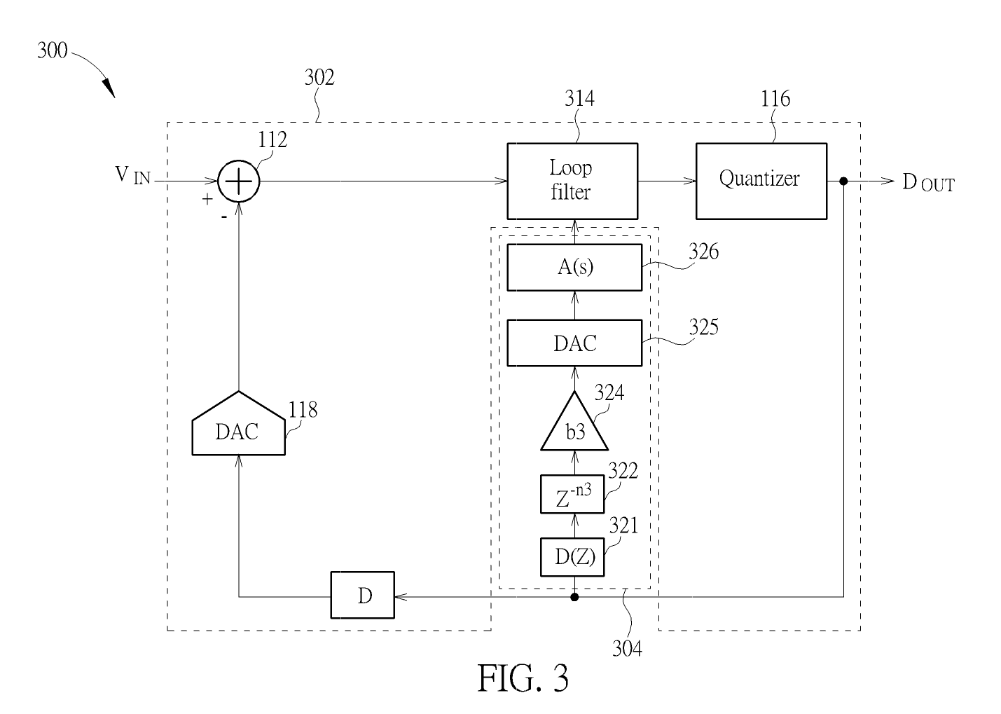

Please refer to FIG. 3, which is a diagram illustrating a delta-sigma modulator using a third ELD adjustment scheme. The delta-sigma modulator 300 includes a delta-sigma modulation loop 302 and an ELD adjustment circuit 304. The delta-sigma modulation loop 302 includes a loop filter 314 and the aforementioned adder 112, quantizer 116 and DAC 118. The ELD adjustment circuit 304 has a pre-processing circuit (e.g., a digital filter) 321 with a digital transfer function D(z), a delay stage 322, a gain stage 324, a DAC 325, and a post-processing circuit (e.g., an analog filter) 325 with an analog transfer function A(s). The delay stage 322 is arranged to delay the digital output D_{OUT} by n3*Ts, where Ts is the sampling period of the quantizer 116, and n3 may be any value required by ELD adjustment/compensation. The gain stage 224 multiplies an output of the delay stage 322 by a feedback coefficient b3. The ELD adjustment circuit 304 is used to inject an analog signal into one integrator/resonator of the loop filter 314. As the additional feedback for ELD adjustment/compensation is coupled to the analog integrator/resonator input of the loop filter 314, the ELD adjustment circuit 304 with analog ELD adjustment is employed. Hence, the DAC 325 converts the digital sample generated from the gain stage 324 into an analog signal. It should be noted that the analog signal injected into the loop filter 314 would undergo a transfer function LF possessed by the loop filter 314. To make the output of the loop filter 314 shown in FIG. 3 equal to the output of the adder 128 shown in FIG. 1, the digital transfer function D(z) and the analog transfer function A(s) are properly designed to have an equivalent transfer function equal to 1/LF. In this example, the pre-processing circuit 321 and the post-processing circuit 326 are both implemented. However, in an alternative design, one of the pre-processing circuit 321 and the post-processing circuit 326 may be omitted, and the other of the pre-processing circuit 321 and the post-processing circuit 326 is properly designed to have a transfer function equal to 1/LF.

With regard to the ELD adjustment scheme shown in FIG. 3, the ELD adjustment is applied to the analog integrator/resonator input of the loop filter 314 via an additional feedback path. However, an analog ELD adjustment/compensation may be realized without an explicit feedback path. For example, it can be done by configuring the loop filter to adjust its phase shift.

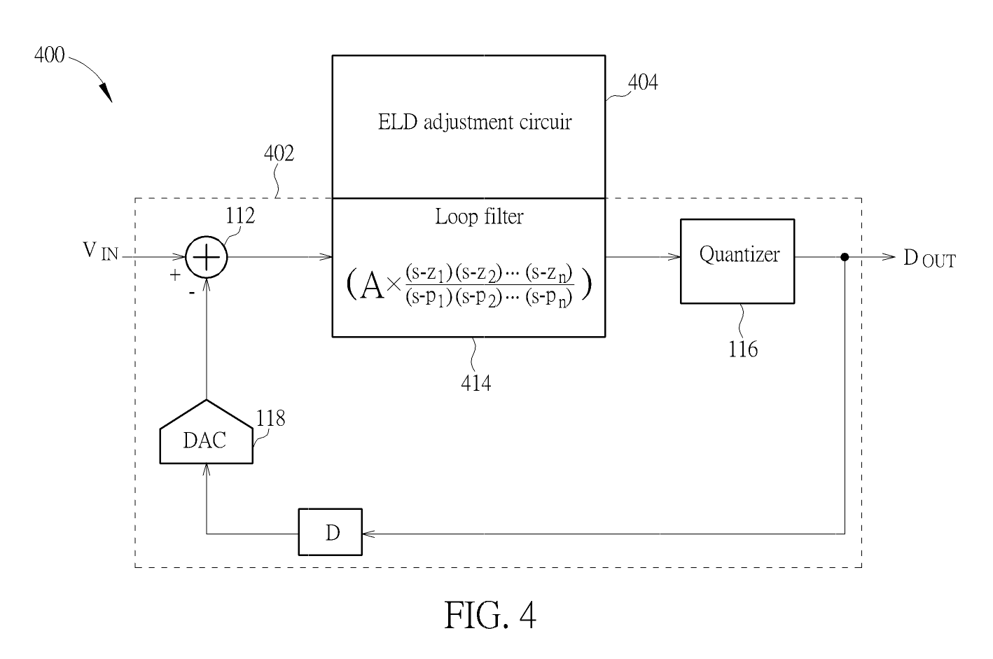

Please refer to FIG. 4, which is a diagram illustrating a delta-sigma modulator using a fourth ELD adjustment scheme. The delta-sigma modulator 400 includes a delta-sigma modulation loop 402 and an ELD adjustment circuit 404. The delta-sigma modulation loop 402 includes the aforementioned adder 112, quantizer 116 and DAC 118, and further includes a loop filter 414, whose transfer function can be expressed with a gain and multiple zero(s) and/or pole(s). For example, the transfer function of the loop filter 414 may be expressed as below:

$$A \times \frac{( s - {z}_{1} ) ( s - {z}_{2} ) … ( s - {z}_{n} )}{( s - {p}_{1} ) ( s - {p}_{2} ) … ( s - {p}_{n} )} ,$$

where A represents the gain, z₁-zₙ represent zeros, and p₁-pₙ represent poles.

The ELD compensation can be realized by controlling pole(s) and/or zero(s) of the loop filter 414 to create either a phase leading effect or a phase lagging effect. For example, a feedforward path across the filter stages may result in a phase leading effect, and an integrator implemented by a slow operational amplifier may lead to a phase lagging behavior. Due to the ELD adjustment circuit 404 with analog ELD adjustment, the analog output of the loop filter 414 shown in FIG. 4 is equal to the analog output of the adder 128 shown in FIG. 1.

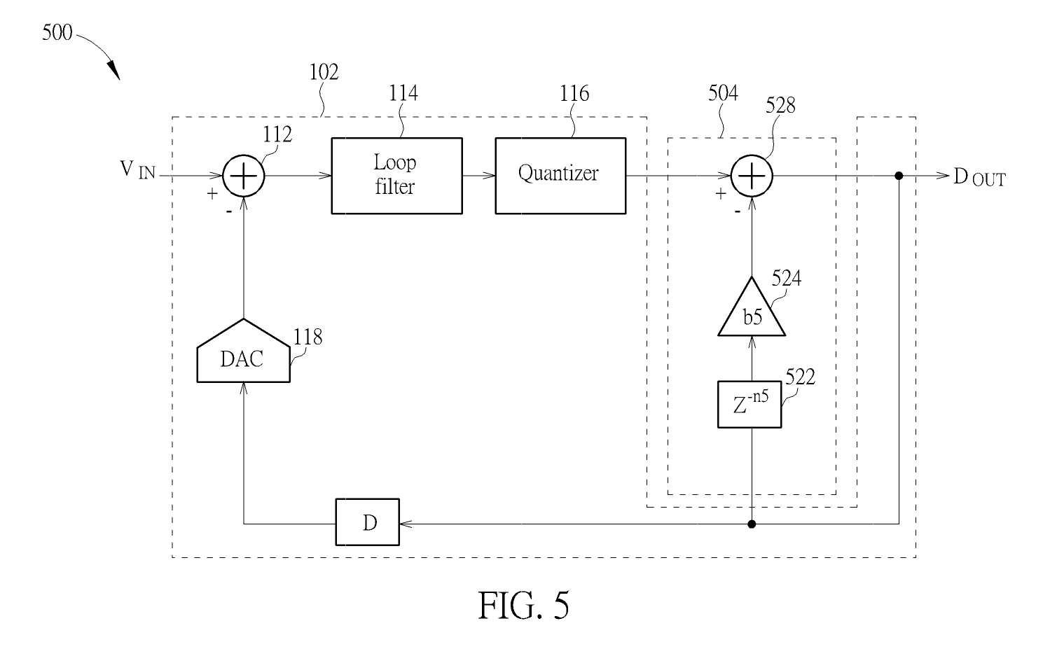

With regard to the ELD adjustment scheme shown in FIG. 1, the ELD adjustment is applied to the analog input of the quantizer 116 via an additional feedback path. Alternatively, an ELD adjustment may be applied to the digital output of the quantizer via an additional feedback path. Please refer to FIG. 5, which is a diagram illustrating a delta-sigma modulator using a fifth ELD adjustment scheme. The delta-sigma modulator 500 includes an ELD adjustment circuit 504 and the aforementioned delta-sigma modulation loop 102. In this example, the ELD of the delta-sigma modulation loop 102 is adjusted/compensated by an additional feedback to an output node of the quantizer 116. As shown in FIG. 5, the ELD adjustment circuit 504 has at least a delay stage 522, a gain stage 524, and an adder 528 (which is configured to perform digital value subtraction). The delay stage 522 is arranged to delay the digital output D_{OUT} by n5*Ts, where Ts is the sampling period of the quantizer 116, and n5 may be any value required by ELD adjustment/compensation. The gain stage 524 multiplies a delayed version of the digital output D_{OUT} by a feedback coefficient b5. As the additional feedback for ELD adjustment/compensation is coupled to the digital output of the quantizer 116, the ELD adjustment circuit 504 with digital ELD adjustment is employed. Hence, the adder 528 performs digital combination based on digital outputs generated from the quantizer 116 and the gain stage 524.

The analog implementation of ELD adjustment/compensation usually demands on high-speed circuits and costs extra power. It is worse when the feedback coefficient is larger. The digital implementation of ELD adjustment/compensation would require extra hardware to manipulate switching/selection of quantization levels. It is worse when the feedback coefficient is a non-integer. Compared to the analog ELD adjustment, the digital ELD adjustment is easy to implement. However, if the feedback coefficient is a non-integer, it is difficult to realize the digital ELD adjustment mentioned above. To benefit from the digital ELD adjustment, the present invention therefore proposes a hybrid ELD adjustment scheme using digital ELD adjustment as well as analog ELD adjustment.

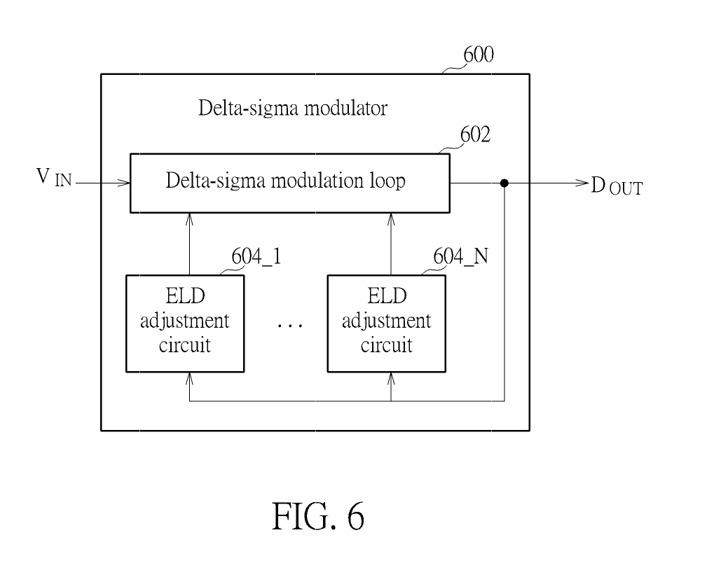

Please refer to FIG. 6, which is a schematic diagram illustrating a delta-sigma modulator using a hybrid ELD adjustment scheme according to an embodiment of the present invention. The delta-sigma modulator 600 includes a delta-sigma modulation loop 602 and a plurality of ELD adjustment circuits 604_1-604_N. It should be noted that only two ELD adjustment circuits are shown in FIG. 6 for illustrative purposes only. In practice, N can be any positive number equal to or larger than two, depending upon actual design requirement/consideration.

The delta-sigma modulation loop 602 is arranged to convert an analog input V_{IN} into a digital output D_{OUT}. The ELD adjustment circuits 604_1-604_N are arranged to perform different ELD adjustments according to the digital output D_{OUT} for jointly adjusting an ELD of the delta-sigma modulation loop 602. In other words, different ELD adjustment schemes are employed for mitigating/eliminating the effects caused by the ELD of the delta-sigma modulation loop 602. By way of example, but not limitation, the ELD adjustment circuits 604_1-604_N may include at least one ELD adjustment circuit with digital ELD adjustment and/or at least one ELD adjustment circuit with analog ELD adjustment. Consider a case where the ELD adjustment circuits 604_1-604_N include at least one ELD adjustment circuit (e.g., 604_N) with digital ELD adjustment and at least one ELD adjustment circuit (e.g., 604_1) with analog ELD adjustment. When the ELD of the delta-sigma modulation loop 602 is a non-integer, a feedback coefficient of the digital ELD adjustment is set by an integer to simplify the hardware implementation. Due to the fact that the ELD of the delta-sigma modulation loop 602 is jointly adjusted/compensated by the multiple ELD adjustment schemes, a feedback coefficient of the analog ELD adjustment is set based on at least the feedback coefficient of the digital ELD adjustment. For example, the feedback coefficient of the analog ELD adjustment can be set by a small value to reduce the power dissipation.

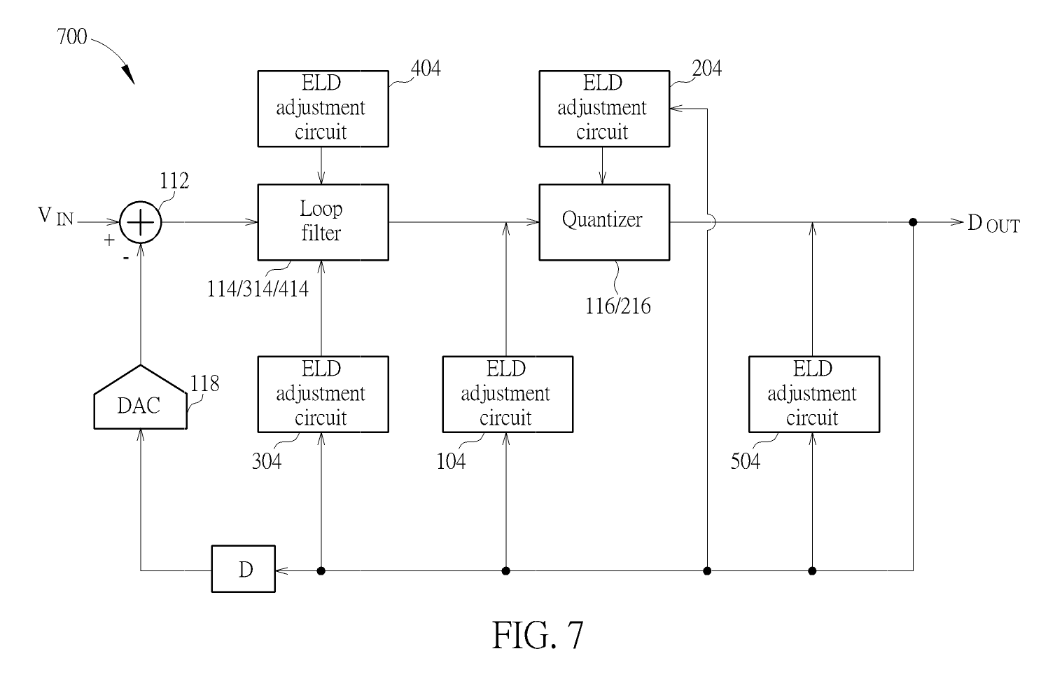

Any of the ELD adjustment circuits 604_1-604_N may be implemented using one of the aforementioned ELD adjustment circuits 104, 204, 304, 404, 504. Please refer to FIG. 7, which is a diagram illustrating one exemplary delta-sigma modulator design based on the structure shown in FIG. 6. The delta-sigma modulator 700 includes a delta-sigma modulation loop composed of aforementioned adder 112, loop filter 114/314/414, quantizer 116/216, and DAC 118, and further includes the aforementioned ELD adjustment circuits 104-504. It should be noted that the delta-sigma modulator 700 may be modified to omit some of the ELD adjustment circuits 104-504. For example, in one preferred embodiment, the ELD adjustment circuits 104, 204, 304 are omitted. As a person skilled in the art can readily understand details of the delta-sigma modulator 700 after reading above paragraphs, further description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A delta-sigma modulator, comprising:
a delta-sigma modulation loop, arranged to convert an analog input into a digital output; and
a plurality of excess loop delay (ELD) adjustment circuits, arranged to perform different ELD adjustments according to the digital output for jointly adjusting an ELD of the delta-sigma modulation loop.

2. The delta-sigma modulator of claim 1, wherein the ELD adjustment circuits comprise at least a first ELD adjustment circuit with digital ELD adjustment.

3. The delta-sigma modulator of claim 2, wherein when the ELD of the delta-sigma modulation loop is a non-integer, a feedback coefficient of the digital ELD adjustment is set by an integer.

4. The delta-sigma modulator of claim 2, wherein the ELD adjustment circuits further comprise at least a second ELD adjustment circuit with analog ELD adjustment.

5. The delta-sigma modulator of claim 4, wherein a feedback coefficient of the digital ELD adjustment is set by an integer, and a feedback coefficient of the analog ELD adjustment is set based on at least the feedback coefficient of the digital ELD adjustment.

6. The delta-sigma modulator of claim 1, wherein the ELD adjustment circuits comprises at least one ELD adjustment circuit with analog ELD adjustment.

7. A delta-sigma modulation method, comprising:
converting an analog input into a digital output through a delta-sigma modulation loop; and
employing different ELD adjustment schemes for jointly adjusting an ELD of the delta-sigma modulation loop according to the digital output.

8. The delta-sigma modulation method of claim 7, wherein the different ELD adjustment schemes comprise at least a first ELD adjustment scheme with digital ELD adjustment.

9. The delta-sigma modulation method of claim 8, wherein the step of jointly adjusting the ELD of the delta-sigma modulation loop comprises:
when the ELD of the delta-sigma modulation loop is a non-integer, setting a feedback coefficient of the digital ELD adjustment by an integer.

10. The delta-sigma modulation method of claim 8, wherein the different ELD adjustment schemes further comprise at least a second ELD adjustment scheme with analog ELD adjustment.

11. The delta-sigma modulation method of claim 10, wherein the step of jointly adjusting the ELD of the delta-sigma modulation loop comprises:
setting a feedback coefficient of the digital ELD adjustment by an integer; and
setting a feedback coefficient of the analog ELD adjustment based on at least the feedback coefficient of the digital ELD adjustment.

12. The delta-sigma modulation method of claim 7, wherein the different ELD adjustment schemes comprises at least one ELD adjustment scheme with analog ELD adjustment.
